(19) United States
(12) Patent Application Publication
(10) Pub. No.: US 2005/0224934 A1
(43) Pub. Date: Oct. 13, 2005

(54) Circuit device

(76) Inventor: Atsushi Kato, Gunma (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 11/046,984

(22) Filed: Jan. 31, 2005

(30) Foreign Application Priority Data
Mar. 26, 2004 (JP) P2004-092560

(51) Int. Cl. H01L 23/48

(52) U.S. Cl. 257/676; 257/692; 257/698; 257/700

(57) ABSTRACT

In the case of mounting a passive element in a circuit device, since an electrode part is tin-plated, the passive element is fixed to a mounting land part by use of a solder material, and wires cannot intersect with each other in a single layer. Accordingly, there are problems such as an increase in a mounting area, a restriction to a reflow temperature in mounting on a printed board, and deterioration of reliability due to solder crack after packaging. The electrode part of the passive element is gold-plated, and a bonding wire is directly fixed to the electrode part. Accordingly, the mounting land part and a pad part for fixing the passive element are reduced, and the wires can intersect with each other even in the single layer. Thus, a packaging density can be improved. Moreover, a restriction that the reflow temperature in mounting the circuit device on the printed board must be set to not more than a melting point of solder can be avoided.

### BACKGROUND OF THE INVENTION

1. Field of the Invention

The present invention relates to a circuit device including a passive element, and more particularly relates to a circuit device having an improved wiring density.

2. Description of the Related Art

With reference to FIGS. 5A and 5B, a conventional circuit device will be described. FIG. 5A is a plan view of the circuit device, and FIG. 5B is a cross-sectional view along the line B-B in FIG. 5A.

As shown in FIG. 5A, a semiconductor element 101 such as an IC, for example, and a plurality of conductive patterns 103 are arranged in a predetermined package region 120 on a supporting substrate 110, for example. The conductive patterns 103 include a pad part 103a to which a bonding wire 108 or the like is fixed, and/or mounting land parts 103b to which both electrode parts 107 of a passive element 106 are fixed. The passive element 100 is, for example, a chip condenser or the like.

The passive element 106 and the semiconductor element 101 are connected to each other through the conductive patterns 103. Specifically, the electrode part 107 of the passive element 106 is fixed to the mounting land part 103b by use of a solder material, Ag paste or the like, and the conductive pattern 103 is extended from the mounting land part 103b. Thereafter, the pad part 103a and an electrode pad 102 of the semiconductor element 101 are connected to each other through the bonding wire 108 or the like. Moreover, the passive elements 106 are connected to each other through the conductive pattern 103 having the mounting land parts 103b on its both ends.

As shown in FIG. 5B, a side of an end of the passive element 106 is tin-plated to form the electrode part 107. In mounting the passive element 106, the element is fixed to the mounting land parts 103b (the conductive pattern 103) by use of the solder material 160. This technology is described for instance in Japanese Patent Application Publication No. 2003-297601.

The electrode part 107 of the passive element 106 is formed by tin plating, which is inexpensive. Since tin has a low melting point and cannot be subjected to thermocompression bonding at a high temperature, the electrode part 107 is fixed to the conductive pattern 103 by use of the solder material 160 in mounting the passive element 106.

In the case of mounting by use of the solder material 160, a fillet made of the solder material 160 is formed in the electrode part 107. Therefore, in order to electrically connect the passive element 106 to the semiconductor element 101, another passive element 103, or the conductive pattern 103, the mounting land part 103b larger than the electrode part 107 is required below the electrode part 107 of the passive element 106. Alternatively, the conductive pattern 103 having the pad part 103a connected to the bonding wire 108 is required. For the reasons described above, reduction in a mounting area makes little progress, and a product packaging density of the circuit device having the passive element 106 mounted thereon is lowered.

Moreover, if wiring becomes complicated and the conductive patterns 103 intersect with each other, a multi-layered structure is formed as indicated by the broken lines in FIG. 5A, and connections are made through through-holes TH. Alternatively, in the case of a single layer structure, it is required to arrange the conductive patterns 103 so as to make a long detour. Specifically, there are problems that, for the connection of the passive element, the multi-layered structure has to be formed by increasing costs and the number of production process, or the mounting area has to be further increased.

Furthermore, in the case of fixing by use of the solder material, a device having a structure subjected to resin sealing has the following problems.

For example, a reflow temperature in mounting on a printed board or the like cannot be set to a melting point of solder or more. This is because, if the reflow temperature reaches the melting point of solder or more, solder is remelted to cause short circuit or package destruction.

Moreover, other than solder, Ag paste may be used for fixing. In this case, if the package is distorted by heat generated after resin sealing, crack occurs in solder or Ag paste. Thus, reliability is deteriorated.

Moreover, a circuit device using lead-free solder mainly made of tin as fixing means has another problem. For example, in the case where an external terminal (external electrode) of a package is fixed to a package board such as a printed board by use of the lead-free solder, or in the case where the external electrode itself is formed of solder, if solder is used for fixing in the package, the solder is required to have a melting point higher than that of the lead-free solder. However, mounting by use of high melting point solder also leads to a problem such as destruction of elements.

Moreover, in the case where the lead-free solder is used for fixing in the package, fixing means outside of the package is mounted by use of low melting point solder. Accordingly, fixing strength is not perfect.

Furthermore, there is a small variety of the lead-free solder, and there is not much difference in the melting point therebetween. Specifically, if a passive element in the package is fixed by use of the lead-free solder, and the external terminal (external electrode) is also fixed to the package board by use of the lead-free solder, there arises a problem since the lead-free solder inside is remelted.

### SUMMARY OF THE INVENTION

The present invention provides a circuit device using lead-free solder mainly made of tin as fixing means that includes a package region in which conductive patterns and a semiconductor element electrically connected to the conductive patterns are arranged, bonding wires, and at least one passive element which is fixed in the package region and has electrode parts provided on its both sides. In the circuit device, one end of the bonding wire is fixed to the electrode part of the passive element, and electrical connections are made by use of the bonding wires.

The present invention also provides a circuit device using lead-free solder mainly made of tin as fixing means that includes a package region in which a semiconductor element and conductive patterns are arranged on a supporting substrate, bonding wires, and at least one passive element which is fixed in the package region and has electrode parts provided on its both sides. In the circuit device, one end of the bonding wire is fixed to the electrode part of the passive element, and electrical connections are made by use of the bonding wires.

The present invention further provides a circuit device using lead-free solder mainly made of tin as fixing means that includes a package region including conductive patterns supported by an insulating resin and a semiconductor element fixed to any of the conductive patterns and the insulating resin, bonding wires, and a passive element which is fixed in the package region and has electrode parts provided on its both sides. In the circuit device, one end of the bonding wire is fixed to the electrode part of the passive element, and electrical connections are made by use of the bonding wires.

The present invention can achieve the following effects.

First, the passive element can be directly and electrically connected to the semiconductor element, the conductive pattern or another passive element by use of the bonding wire. Specifically, a mounting land part for fixing the electrode part of the passive element, and a pad part for connection to an electrode pad of the semiconductor element close to the passive element are not required. Thus, reduction in a mounting area can be realized.

Second, by fixing the bonding wire directly to the passive element, electrical connection to other constituent components is realized. Thus, a part of the conductive pattern can be disposed below the bonding wire. In a conventional case, since the passive element is connected to the other constituent components by use of the conductive pattern, if the conductive pattern intersects with the conductive pattern connected to the passive element, it is required to form a two-layered wiring structure. Meanwhile, according to an embodiment of the present invention, the conductive patterns can intersect with each other in a single layer structure. Thus, a packaging density can be improved.

Third, the passive element can be bonded on the semiconductor element. Thus, the mounting area can be reduced, and high-frequency characteristics can be improved by shortening the bonding wires connected to the semiconductor element.

Fourth, the passive element can be mounted by use of an adhesive or an adhesive sheet. Thus, there is no longer a restriction that a reflow temperature in mounting a module of the circuit device on a printed board must be set to not more than a melting point of solder.

Fifth, since fixing can be performed without using a solder material, occurrence of cracks in the solder material due to stress on a resin package can be prevented. Thus, reliability is improved.

Sixth, since a fillet made of the solder material is not formed on the side of the passive element, an area for mounting the passive element can be reduced. Thus, the packaging density of the entire device can be improved.

Seventh, in a circuit device using lead-free solder as fixing means, lead-free solder can be used to fix an external terminal (external electrode) to the package board. Alternatively, lead-free solder can be adopted to form the external electrode itself.

Since there is a small variety of lead-free solder, and there is no difference in a melting point therebetween, lead-free solder cannot be used for both the inside of the package and the outside of the package. According to the embodiment, since the bonding wire is used for electrical connection of the passive element in the package, lead-free solder can be used for connection between the external terminal and the package board.

Eighth, since the mounting land part which has been heretofore required for electrical connection of the passive element is no longer required, the passive element can be disposed close to the semiconductor element. Therefore, noise is absorbed well in the case where the passive element is, for example, a chip condenser or the like.

### BRIEF DESCRIPTION OF THE DRAWINGS

FIG. 1A is a plan view and FIG. 1B is a cross-sectional view showing a circuit device of the preferred embodiment.

FIGS. 2A to 2C are cross-sectional views showing package examples in which the circuit device of the preferred embodiment is mounted.

FIGS. 3A and 3B are cross-sectional views showing package examples in which the circuit device of the preferred embodiment is mounted.

FIG. 4A is a plan view and FIG. 4B is a cross-sectional view showing a package example in which the circuit device of the preferred embodiment is mounted.

FIG. 5A is a plan view and FIG. 5B is a cross-sectional view showing a conventional circuit device.

### DESCRIPTION OF THE EMBODIMENTS

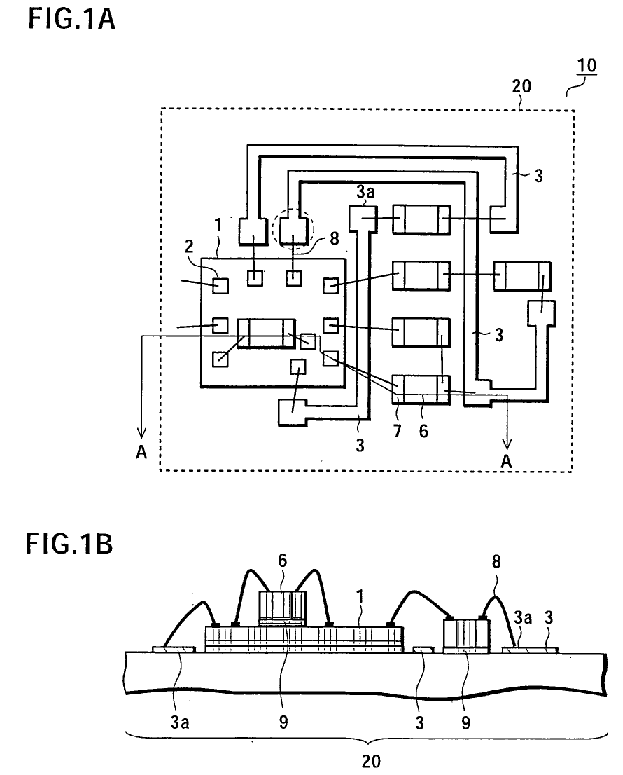

With reference to FIGS. 1 to 4, an embodiment of a circuit device according to an embodiment of the present invention will be described.

FIGS. 1A and 1B show the circuit device of this embodiment. FIG. 1A is a plan view, and FIG. 1B is a cross-sectional view along the line A-A in FIG. 1A.

The circuit device 10 of this embodiment includes a semiconductor element 1, conductive patterns 3, passive elements 6, and bonding wires 8.

As shown in FIG. 1A, the circuit device has a package region 20 in a predetermined region indicated by the broken line, for example. Note that, in the package region 20 of this embodiment, at least the semiconductor element 1 such as an IC, for example, the conductive patterns 3, and the passive elements 6 are disposed. Here, the package region 20 is one continuous region indicated by the dotted line forming a predetermined circuit. The conductive pattern 3 has a pad part 3a on its end, to which the bonding wire 8 is fixed.

In this embodiment, the passive element 6 is a chip element having electrode parts 7 on its both ends, such as a chip resistor, a chip condenser, an inductance, a thermistor, an antenna, and an oscillator. The electrode parts 7 are formed on the both ends of the passive element 6 formed to be long and narrow, and surfaces thereof are gold-plated. In this embodiment, electrical connection is realized by fixing one end of the bonding wire 8 to the electrode part 7 of the passive element 6. The passive elements 6 are fixed in the package region 20 by use of fixing means which is never remelted. To be more specific, an insulating or conductive adhesive material (an adhesive, an adhesive sheet or the like) is used.

As shown in FIG. 1A, the passive element 6 of this embodiment is bonded in a region where no conductive patterns 3 are disposed, for example. However, by use of the insulating adhesive material, the passive element 6 can also be bonded on the densely provided conductive patterns 3.

In either case, since electrical connection of the passive element 6 is made by use of the bonding wire 8, the element can be fixed in the package region 20 without considering arrangement of the conductive patterns 3.

Moreover, the passive element 6 may be fixed on the semiconductor element 1 by use of the insulating adhesive material. Thus, stack mounting of the passive element 6 and the semiconductor element 1 can be realized.

The other end of the bonding wire 8 fixed to the passive element 6 is connected to an electrode pad 2 of the semiconductor element 1 and/or the pad part 3a of the conductive pattern 3. Alternatively, the electrode parts 7 of the passive element 6 are connected to each other through the bonding wire 8.

Thus, the electrode parts 7 are gold-plated so as to enable bonding through the bonding wire 8. Specifically, metal on an uppermost surface of the electrode part 7 is determined based on a material (Au, Al or the like) of the bonding wire 8.

Specifically, it is important that the passive element 6 is not fixed to a mounting land part by use of a solder material, Ag paste or the like, but is fixed to the package region 20 by use of an adhesive material such as adhesive resin and the adhesive sheet, and that the element is electrically connected by use of the bonding wire.

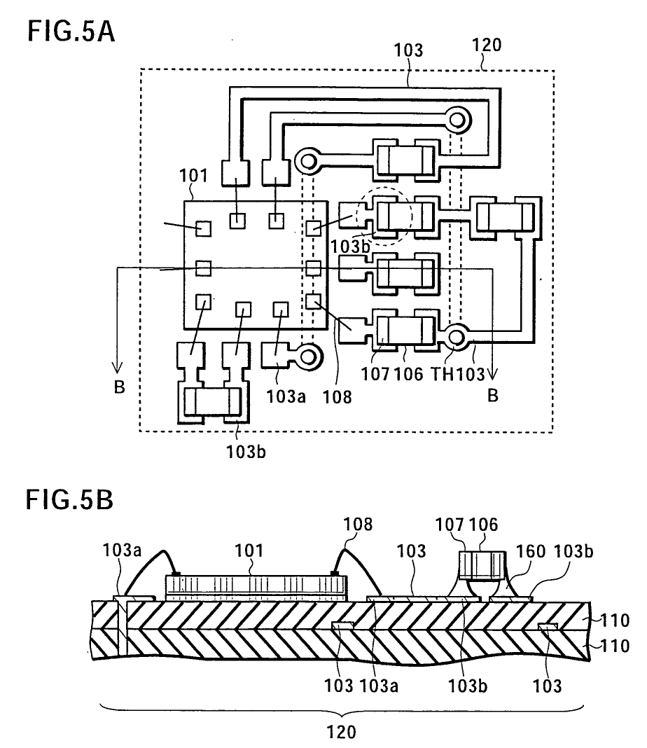

Accordingly, the mounting land part 103b (indicated by the broken circle in FIG. 5A) becomes unnecessary, to which an electrode part of a passive element has been heretofore fixed. Moreover, the pad part 3a for connecting the electrode pad of the adjacent semiconductor element 1 to the passive element 6 is also no longer required. In other words, a mounting area can be reduced. Moreover, the semiconductor element 1 and the passive element 6 can be disposed close to each other. Thus, when the passive element 6 is, for example, a condenser or the like, noise is absorbed well.

Note that, also in this embodiment, in the case where the passive element 6 distant from the semiconductor element 1 is connected to the semiconductor element 1, the conductive pattern 3 is extended. Thus, it is required to provide the pad part 3a (indicated by the broken circle in FIG. 1A) close to the electrode pad 2 of the semiconductor element 1, and to have the passive element 6 wire-bonded thereto. However, even in the case where the conductive pattern 3 is extended as described above, on the passive element 6 side, the pad part 3a of the conductive pattern 3 is not required to have a size which enables fixing of the electrode part 7. It is only necessary to secure an area which enables wire bonding. Moreover, since the conductive pattern 3 can be provided below the bonding wire 8 connected to the passive element 6, an increase in the mounting area can be prevented.

With reference to the cross-sectional view of FIG. 1B, description will be given of a state where the passive element 6 is fixed in the package region.

The passive element 6 is bonded with an adhesive material 9 in the package region 20. Bonding of the passive element 6 is performed by use of an adhesive resin or an adhesive sheet. Accordingly, no fillet is formed unlike the case of the solder material 160. Therefore, a mounting area required to mount the passive element 6 is about the same as a planar size of the passive element 6.

As shown in FIG. 1B, in a spot where the passive element 6 and the semiconductor element 1 are close to each other, connection is directly made by the bonding wire 8. Moreover, since the passive element 6 can be stacked on the semiconductor element 1 as described above, the mounting area can be significantly reduced. In this case, no conductive pattern 3 is required to connect the semiconductor element 1 to the passive element 6, and the bonding wire 8 can be shortened. Thus, there is an advantage that good high-frequency characteristics can be obtained by reduction in conductance, and noise absorption is speeded up.

As the adhesive material used to fix the passive element 6 on the semiconductor element 1, a material having a relatively high viscosity may be adopted. If the material is less fluid and has a viscosity capable of retaining a certain thickness when applied, impact on the passive element 6 in wire bonding can be absorbed, and stress on the semiconductor element 1 can be relieved. Moreover, if the material has a thickness of about several ten μm to 100 μm when applied, for example, it is possible to make allowance by that much for accuracy of alignment in a vertical direction (height direction) in fixing.

Furthermore, below the bonding wire 8 having one end fixed to the passive element 6, a part of the conductive pattern 3 can be disposed. If the wires intersect with each other as described above, it has been heretofore required to form the conductive patterns to have a multi-layered wiring structure, and to make connections through through-holes. However, in this embodiment, the wires can intersect with each other in a single layer structure.

As described above, it is found out that various effects are achieved by connecting the passive element 6 through the bonding wire or by adopting a chip element connected through the bonding wire.

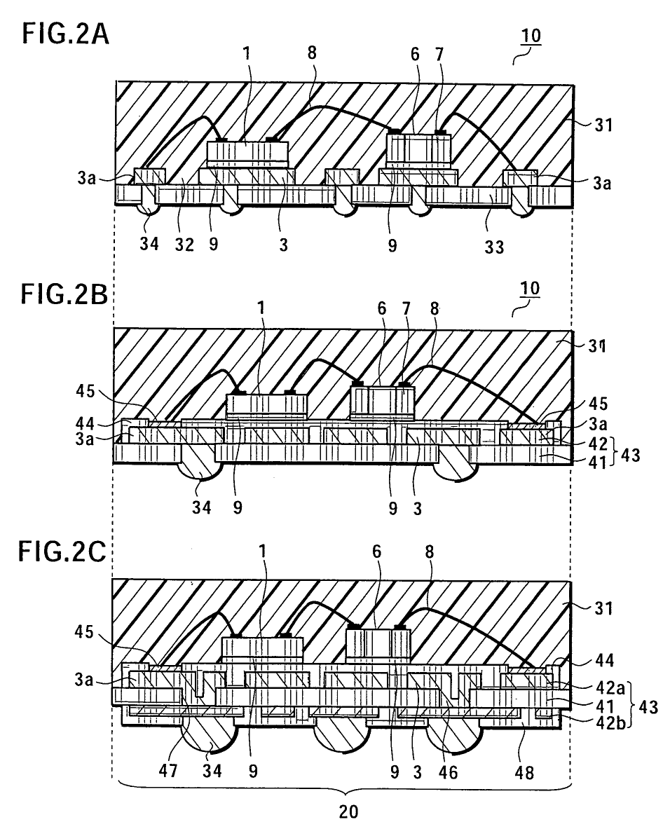

Next, with reference to FIGS. 2 to 4, package examples of the above-described circuit device will be described.

First, with reference to FIGS. 2A to 2C, FIG. 2A shows the circuit device which requires no package board, FIG. 2B shows one packaged by using a resin sheet having conductive patterns, and FIG. 2C is a cross-sectional view in the case of using a substrate having a multi-layered wiring structure

The circuit device shown in FIG. 2A can be realized in such a manner that, after elements as shown in FIG. 2A are mounted and molded on a supporting substrate having desired conductive patterns, for example, the supporting substrate is removed. Moreover, the device can be realized in such a manner that, after a Cu foil is half-etched and the elements are mounted and molded, the Cu foil present on a rear surface of a package is etched back. Furthermore, the device can also be realized by molding while allowing a rear surface of a punched lead frame to abut on a lower mold. Here, description will be given by taking the second case of adopting half etching as an example.

Specifically, the conductive patterns 3 are disposed in the package region 20. The conductive patterns 3 are embedded in and supported by an insulating resin 31, and rear surfaces thereof are exposed from the insulating resin 31. In this case, the conductive patterns 3 are formed of a conductive foil mainly made of Cu, a conductive foil mainly made of Al, a conductive foil made of alloys such as Fe—Ni, or the like. However, other conductive materials can also be used, and particularly, a conductive material which can be etched is applicable.

In this case, in manufacturing steps, isolation trenches 32 not as deep as a thickness of a sheet-like conductive foil are provided in the conductive foil by half etching. Accordingly, the conductive patterns 3 are formed. Thereafter, the isolation trenches 32 are filled with the insulating resin 31, and are joined with and firmly bonded to a curved structure of sides of the conductive patterns. Subsequently, by etching the conductive foil below the isolation trenches 32, the conductive patterns 3 are individually separated and supported by the insulating resin 31.

Specifically, the insulating resin 31 seals the entire package region 20, here, the semiconductor element 1, the passive element 6 and the bonding wires 8 while exposing the rear surfaces of the conductive patterns 3. As the insulating resin 31, a thermosetting resin formed by transfer molding or a thermoplastic resin formed by injection molding can be adopted. To be more specific, a thermosetting resin such as an epoxy resin or a thermoplastic resin such as a polyimide resin and polyphenylene sulfide can be used. Moreover, as the insulating resin, all kinds of resin can be adopted as long as the resin is one hardened by use of a mold or one capable of covering by dipping or coating. In the package described above, the insulating resin 31 also has a function of supporting the entire circuit module as well as sealing the semiconductor element 1 and the like. As described above, the entire circuit device is sealed by the insulating resin 31. Thus, separation of the semiconductor element 1 and the passive element 6 from the conductive patterns 3 can be prevented.

The semiconductor element 1 is fixed on the conductive pattern (land) 3 in the package region 20 by use of the insulating or conductive adhesive 9 according to usage. In addition, the electrode pad has the bonding wire 8 thermo-compression bonded thereto and is connected to the conductive pattern 3 and the passive element 6.

In the case of FIG. 2A, the passive element 6 is also fixed on the conductive pattern 3 in the package region 20 by use of the adhesive 9. Here, in this embodiment, electrical connection between the passive element 6 and the other constituent components such as the semiconductor element 1 is realized by use of the bonding wires 8. Specifically, the passive element 6 may not be fixed on the conductive pattern 3. However, in the case of the package structure shown in FIG. 2A, strength of supporting the passive element 6 can be improved by fixing the element on the conductive pattern 3.

One end of the bonding wire 8 is directly fixed to the electrode part 7 of the passive element 6, and the other end thereof is connected to any of the electrode pad of the semiconductor element 1, the conductive pattern 3, and the electrode part 7 of the other passive element 6.

Note that a thickness of the insulating resin 31 is controlled so as to cover up to about 100 μm from a top of the bonding wire 8 in the circuit device 10. This thickness can be increased or reduced in consideration for strength.

A rear surface of the insulating resin 31 and the rear surfaces of the conductive patterns 3 are substantially aligned with each other. In addition, on the rear surfaces, an insulating resin (for example, a solder resist) 33 having openings in desired regions is provided. Thereafter, a conductive material such as solder is deposited on the exposed conductive patterns 3 to be external electrodes. Accordingly, back electrodes 34 are formed. Thus, the circuit device is completed.

In this event, as solder which forms a part of the back electrode (external electrode) 34 and becomes connection means with the package board, lead-free solder mainly made of tin can be employed. There is a small variety of lead-free solder, and there is not much difference in a melting point therebetween. Therefore, in the structure shown in FIG. 2A, if lead-free solder is also used as fixing means in the package, lead-free solder in the package is remelted when the package is fixed to the package board.

However, in this embodiment, the passive element 6 in the package is fixed by use of an adhesive material which is never remelted, and electrical connections are realized by the bonding wires. In other words, lead-free solder can be used for the back electrode 34. Moreover, in FIG. 2A, by covering the conductive patterns 3 with the insulating resin, the passive element 6 can be fixed in the package region 20 regardless of arrangement of the conductive patterns 3.

Next, according to the structure as shown in FIG. 2B, flexibility of layout of the conductive patterns 3 can be improved.

In the package region 20, the conductive patterns 3 are embedded in and supported by the insulating resin 31 integrally with the other constituent components of the circuit device 10. As described later, the conductive patterns 3 in this case are formed in such a manner that an insulating resin sheet 43 obtained by forming a conductive film 42 on a surface of an insulating resin 41 is prepared, and the conductive film 42 is patterned.

The insulating resin 41 is formed of an insulating material made of polymers, such as a polyimide resin and an epoxy resin. Moreover, a filler may be mixed therein in consideration for thermal conductivity. As a material of the filler, glass, silicon oxide, aluminum oxide, aluminum nitride, silicon carbide, boron nitride, and the like can be used. A film thickness of the insulating resin 41 is about 10 μm to 100 μm in the case of adopting a casting method for obtaining a sheet by applying a material in the form of paste. Moreover, a commercially available insulating resin has a minimum film thickness of 25 μm.

The conductive film 42 may be formed by use of a material mainly made of Cu, Al, Fe, Fe—Ni or a material of a heretofore known lead frame. The conductive film may be deposited on the insulating resin 41 by use of a plating method, a vapor deposition method or a sputtering method, or may have a metal foil attached thereto, which is formed by use of a rolling method or the plating method.

The conductive patterns 3 are formed in such a manner that the conductive film 42 is covered with a photoresist having desired patterns, and the desired patterns are formed by chemical etching.

The conductive patterns 3 are covered with an overcoat resin 44 except for the pad part 3a subjected to wire bonding. The overcoat resin 44 is obtained by attaching an epoxy resin or the like, which is dissolved in a solvent, by screen printing, and thermosetting the resin.

Moreover, in consideration for bonding properties, a plated film 45 such as Au and Ag is formed on the pad part 3a. This plated film 45 is selectively subjected to electro-less plating on the pad part 3a by use of the overcoat resin 44 as a mask, for example.

The semiconductor element 1 and the passive element 6 are die-bonded, as a bare chip, on the overcoat resin 44 in the package region 20 by use of the insulating adhesive (adhesive resin) 9, for example.

Each of the electrode pads of the semiconductor element 1 is connected to the pad part 3a through the bonding wire 8.

One end of the bonding wire 8 is directly fixed to the electrode part 7 of the passive element 6, and the other end thereof is connected to any of the semiconductor element 1, the pad part 3a and the other passive element 6.

The insulating resin sheet 43 is covered with the insulating resin 31. Thus, the conductive patterns 3 are also embedded in the insulating resin 31. As a molding method, transfer molding, injection molding, coating, dipping, and the like can also be adopted. However, in consideration for mass productivity, transfer molding and injection molding are suitable.

On the back, a rear surface of the insulating resin sheet 43, that is, the insulating resin 41 is exposed. Openings are formed in desired positions of the insulating resin 41, and external electrodes 34 are provided in portions where the conductive patterns 3 are exposed. For the external electrodes 34, for example, lead-free solder or the like can be employed.

According to the structure described above, the semiconductor element 1 and the passive element 6 are electrically insulated from the conductive patterns 3 thereunder by use of the overcoat resin 44. Thus, the conductive patterns 3 can be freely laid out even below the semiconductor element 1.

For example, in FIG. 2A, the mounting area can be reduced by disposing a part of the conductive pattern 3 below the bonding wire 8 fixed to the passive element 6. However, by adopting the structure of FIG. 2B, such a conductive pattern 3 can also be disposed below the semiconductor element 1 or the passive element 6. The mounting area is further reduced, and flexibility of layout is further improved.

The description has been given above by taking, as an example, the case of the insulating resin sheet 43 having the conductive patterns 3 formed therein. However, without being limited thereto, the conductive patterns 3 shown in FIG. 2A may be covered with the overcoat resin 44. Moreover, the conductive patterns 3 provided on a supporting substrate such as a flexible sheet may be covered with the overcoat resin 44. In either case, the conductive patterns 3 can be laid out below the semiconductor element 1. Thus, a package with improved flexibility of layout can be realized.

Next, FIG. 2C shows the circuit device in which a multi-layered wiring structure of the conductive patterns 3 is realized. Note that the same constituent components as those in FIG. 2B are denoted by the same reference numerals, and description will be omitted.

In the package region 20, the conductive patterns 3 are embedded in and supported by the insulating resin 31 integrally with the other constituent components of the circuit device 10. As described later, the conductive patterns 3 in this case are formed in the following manner. Specifically, the insulating resin sheet 43 is prepared, which is obtained by forming a first conductive film 42a on substantially the entire surface of the insulating resin 41 and forming a second conductive film 42b on substantially the entire rear surface thereof. Thereafter, these conductive films 42 are patterned.

The insulating resin 41, the first conductive film 41a and the second conductive film 42b are formed by use of the same materials as those in the case of FIG. 2B. The conductive patterns 3 are formed in such a manner that the first and second conductive films 42a and 42b are covered with a photoresist having desired patterns, and the desired patterns are formed by chemical etching.

Moreover, in FIG. 2C, the conductive patterns 3, which are separated into upper and lower layers with the insulating resin 41 interposed therebetween, are electrically connected to each other by multi-layered connection means 46. The multi-layered connection means 46 is obtained by burying a plated film such as Cu in through-holes 47. Although, here, Cu is used as the plated film, Au, Ag, Pd and the like may be used.

The conductive patterns 3 on the mounting surface are covered with the overcoat resin 44 except for the pad part 3a to be wire-bonded. In the pad part 3a, the plated film 45 is provided.

The semiconductor element 1 and the passive element 6 are die-bonded, as a bare chip, on the overcoat resin 44 in the package region 20 by use of the insulating adhesive (adhesive resin) 9, for example.

Each of the electrode pads of the semiconductor element 1 is connected to the pad part 3a through the bonding wire 8. One end of the bonding wire 8 is directly fixed to the electrode part 7 of the passive element 6, and the other end thereof is connected to any of the semiconductor element 1, the pad part 3a and the other passive element 6.

The insulating resin sheet 43 is covered with the insulating resin 31. Thus, the conductive patterns 3 formed of the first conductive film 42a are also embedded in and integrally supported by the insulating resin 31.

The conductive patterns 3 formed of the second conductive film 42b below the insulating resin are exposed from the insulating resin 31. However, the conductive patterns are integrally supported by covering a part of the insulating sheet 43 with the insulating resin 31, and are electrically connected to the conductive patterns 3 formed of the first conductive film 42a through the multi-layered connection means 46. Thus, the multi-layered wiring structure is realized. Most of the conductive patterns 3 in the lower layer are covered with an overcoat resin 48 while portions where external electrodes 34 are formed are exposed. Specifically, the overcoat resin 48 is obtained by screen printing an epoxy resin or the like, which is dissolved in a solvent. In the exposed portions, the external electrodes 34 are provided by reflowing solder or by screen printing solder cream. For the external electrodes 34, lead-free solder or the like can be adopted, for example.

Moreover, the external electrodes 34 can also be accomplished by use of bump electrodes obtained by etching the second conductive film 42b and covering a surface thereof with a gold-plated or palladium-plated film.

In the multi-layered wiring structure as described above, not only the conductive patterns 3 below the bonding wire 8 connected to the passive element 6 but also the conductive patterns 3 required to make a long detour on the package region 20 can be laid out below the semiconductor element 1 and the passive element 6. Thus, a chip size can be reduced.

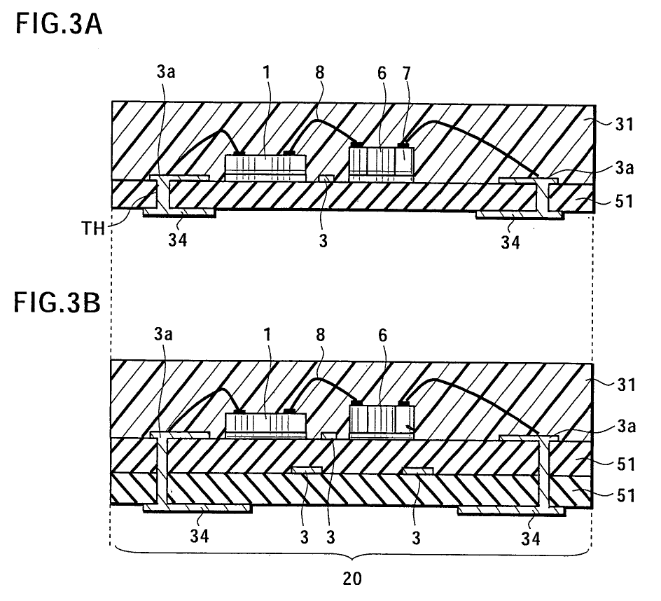

Next, with reference to FIGS. 3A and 3B, description will be given of examples of a chip size package using a supporting substrate. FIG. 3A shows a package in the case where no overcoat resin 44 is required in the package shown in FIG. 2C. FIG. 3B shows a package in the case of a multi-layered wiring structure including three layers or more.

A supporting substrate 51 is an insulating substrate such as a glass epoxy substrate. Note that a flexible sheet can also be used as the supporting substrate 51.

A Cu foil is pressure-bonded to a surface of the glass epoxy substrate 51, patterned conductive patterns 3 are arranged, and the back electrodes (external electrodes) 34 for external connection are provided on a rear surface of the substrate 51. Through through-holes TH, the conductive patterns 3 and the back electrodes 34 are electrically connected to each other.

On the surface of the substrate 51, the semiconductor element 1 and the passive element 6 are fixed by use of the adhesive 9. The bonding wires 8 are pressure-bonded to the electrode pads of the semiconductor element 1, and electrical connections to the other constituent components of the circuit device 10 are realized.

One end of the bonding wire 8 is directly fixed to the electrode part 7 of the passive element 6, and the other end thereof is connected to the semiconductor element 1, the conductive pattern 3 and the other passive element 6.

The semiconductor element 1, the passive element 6, the conductive patterns 3, and the bonding wires 8 are sealed by use of the insulating resin 31 and are supported integrally with the substrate 51. As a material of the insulating resin 31, a thermosetting resin formed by transfer molding or a thermoplastic resin formed by injection molding can be adopted. As described above, by sealing the entire circuit device by use of the insulating resin 31, separation of the semiconductor element 1 and the passive element 6 from the conductive patterns 3 can be prevented. Specifically, the passive element 6 is bonded to the conductive pattern 3 by use of the two constituent components including the adhesive 9 and the insulating resin 31.

Meanwhile, a ceramic substrate may be used as the supporting substrate 51. In this case, the conductive patterns 3 and the back electrodes 34 are provided by printing and sintering conductive paste on the surface and rear surface of the substrate 51, and are connected to each other through the through-holes TH. Moreover, the substrate 51 and the circuit device 10 are integrally supported by the insulating resin 31. The external electrodes 34 are fixed to the package substrate by use of such as solder and lead-free solder can be adopted in this case.

Moreover, as shown in FIG. 3B, the multi-layered wiring structure can be formed also in the case of having a plurality of supporting substrates 51 by providing the conductive patterns 3 to be wiring layers for each of the supporting substrates 51 and connecting the conductive patterns 3 in upper and lower layers to each other through through-holes TH.

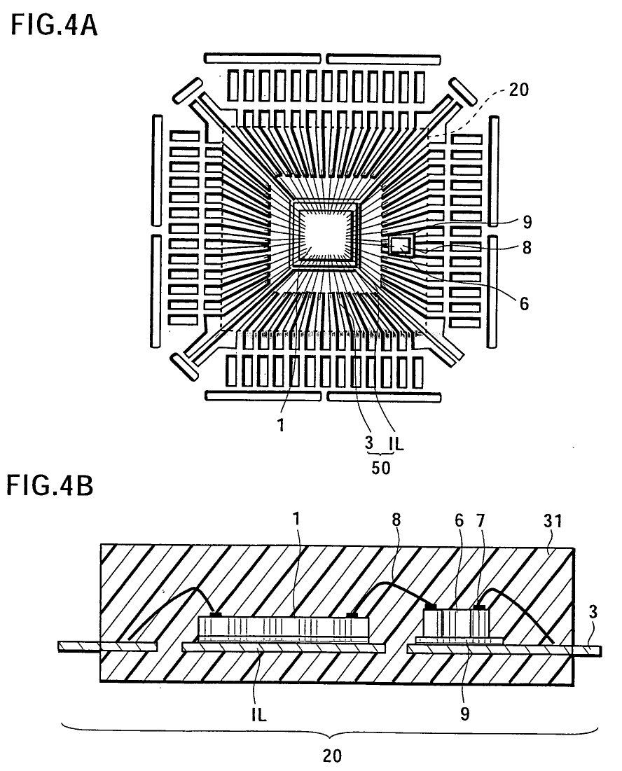

Furthermore, FIGS. 4A and 4B show a package example in the case of adopting a lead frame as a supporting substrate. FIG. 4A is a plan view, and FIG. 4B is a cross-sectional view along the line B-B.

The lead frame 50 to be the supporting substrate has an island IL and a plurality of leads 3 to be conductive patterns in the package region 20. In the island IL, a bare semiconductor element 1 is fixed by use of the adhesive 9 or the like. Electrode pads of the semiconductor element 1 have the bonding wires 8 pressure-bonded thereto and are electrically connected to the leads 3.

The passive element 6 is bonded on the leads 3 by use of an insulating adhesive sheet 9. To be more specific, the passive element 6 is bonded on the plurality of leads 3. One end of the bonding wire 8 is directly fixed to the electrode part 7 of the passive element 6, and the other end thereof is connected to any of the semiconductor element 1, the lead 3 and another passive element 6 similarly bonded by use of the insulating adhesive sheet. Alternatively, the passive element 6 may be bonded on the island IL.

The insulating resin 31 seals the island IL, the circuit device 10, and a part of the leads 3. As a material of the insulating resin 31, a thermosetting resin formed by transfer molding or a thermoplastic resin formed by injection molding can be adopted. The leads 3 are partially drawn out from sides of the insulating resin 31 and are mounted on a printed board or the like by use of lead-free solder or the like.

Note that, although not shown, in the package as described above, sealing may be performed by use of a metal case or other casing members, instead of the insulating resin 31.

Moreover, in fixing the passive element 6 in the package region 20, the electrode parts 7 may be fixed to the conductive patterns 3, which are insulated from each other, by use of a conductive adhesive material. Thus, electrical connection of the passive element 6 can also be made by using both the bonding wires 8 and the conductive patterns 3.

1. A circuit device using lead-free solder mainly made of tin as fixing means, comprising:
a package region in which conductive patterns and a semiconductor element electrically connected to the conductive patterns are arranged;
bonding wires; and
at least one passive element which is fixed in the package region and has electrode parts provided on its both sides,
wherein one end of the bonding wire is fixed to the electrode part of the passive element, and electrical connections are made by use of the bonding wires.

2. A circuit device using lead-free solder mainly made of tin as fixing means, comprising:
a package region in which a semiconductor element and conductive patterns are arranged on a supporting substrate;
bonding wires; and
at least one passive element which is fixed in the package region and has electrode parts provided on its both sides,
wherein one end of the bonding wire is fixed to the electrode part of the passive element, and electrical connections are made by use of the bonding wires.

3. The circuit device according to claim 2, wherein at least the conductive patterns, the semiconductor element, the passive element, and the bonding wires are covered with a resin layer and are supported integrally with the supporting substrate.

4. A circuit device using lead-free solder mainly made of tin as fixing means, comprising:
a package region including conductive patterns supported by an insulating resin and a semiconductor element fixed to any of the conductive patterns and the insulating resin;
bonding wires; and
a passive element which is fixed in the package region and has electrode parts provided on its both sides,
wherein one end of the bonding wire is fixed to the electrode part of the passive element, and electrical connections are made by use of the bonding wires.

5. The circuit device according to claim 4, wherein at least the conductive patterns, the semiconductor element, the passive element, and the bonding wires are covered with and integrally supported by the insulating resin.

6. The circuit device according to claim 1, wherein the passive element is bonded by using any of resin and a sheet.

7. The circuit device according to claim 1, wherein the other end of the bonding wire is connected to any of the semiconductor element and the conductive pattern.

8. The circuit device according to claim 1, wherein the other end of the bonding wire is fixed to an electrode part of another passive element.

9. The circuit device according to claim 1, wherein the electrode part of the passive element is gold-plated.

10. The circuit device according to claim 1, wherein the passive element is fixed on the semiconductor element.

11. The circuit device according to claim 1, wherein, below the bonding wire fixed to the passive element, a part of the conductive pattern is disposed.

12. The circuit device according to claim 1, wherein the bonding wire is thermo-compression bonded to the electrode part of the passive element.

13. The circuit device according to claim 1, wherein the passive element is fixed in the package region by use of another fixing means which is never remelted.

14. The circuit device according to claim 2, wherein the passive element is bonded by using any of resin and a sheet.

15. The circuit device according to claim 2, wherein the other end of the bonding wire is connected to any of the semiconductor element and the conductive pattern.

16. The circuit device according to claim 2, wherein the other end of the bonding wire is fixed to an electrode part of another passive element.

17. The circuit device according to claim 2, wherein the electrode part of the passive element is gold-plated.

18. The circuit device according to claim 2, wherein the passive element is fixed on the semiconductor element.

19. The circuit device according to claim 2, wherein, below the bonding wire fixed to the passive element, a part of the conductive pattern is disposed.

20. The circuit device according to claim 2, wherein the bonding wire is thermo-compression bonded to the electrode part of the passive element.

21. The circuit device according to claim 2, wherein the passive element is fixed in the package region by use of another fixing means which is never remelted.

22. The circuit device according to claim 4, wherein the passive element is bonded by using any of resin and a sheet.

23. The circuit device according to claim 4, wherein the other end of the bonding wire is connected to any of the semiconductor element and the conductive pattern.

24. The circuit device according to claim 4, wherein the other end of the bonding wire is fixed to an electrode part of another passive element.

25. The circuit device according to claim 4, wherein the electrode part of the passive element is gold-plated.

26. The circuit device according to claim 4, wherein the passive element is fixed on the semiconductor element.

27. The circuit device according to claim 4, wherein, below the bonding wire fixed to the passive element, a part of the conductive pattern is disposed.

28. The circuit device according to claim 4, wherein the bonding wire is thermo-compression bonded to the electrode part of the passive element.

29. The circuit device according to claim 4, wherein the passive element is fixed in the package region by use of another fixing means which is never remelted.
